(19) United States
(12) Patent Application Publication
(10) Pub. No.: US 2025/0391966 A1
(43) Pub. Date: Dec. 25, 2025

(54) FIRE RESISTANT ENCLOSURE FOR BATTERIES AND INVERTERS AND BATTERIES AND INVERTERS CONTAINING THE SAME

(71) Applicant: SABIC GLOBAL TECHNOLOGIES B.V., Bergen op Zoom (NL)

(72) Inventors: Carlos PEREIRA CADENA, Putnam Valley, NY (US); Jeffrey Alan ESHENAUR, Hamilton, MI (US); Koffi Leonard DAGNON, COMMERCE TOWNSHIP, MI (US)

(21) Appl. No.: 18/879,626

(22) PCT Filed: Jun. 28, 2023
(86) PCT No.: PCT/EP2023/067713

§ 371 Date: Dec. 27, 2024

(30) Foreign Application Priority Data
Jun. 29, 2022 (EP) 22181917.0

(51) Int. Cl. H01M 50/131; C23C 18/16; C23C 18/32; C23C 18/38; C23C 18/42; H01M 50/119; H01M 50/121; H01M 50/124; H01M 50/128; H01M 50/133; H01M 50/224; H01M 50/227; H01M 50/231; H01M 50/233; H01M 50/24; H01M 50/249

(52) U.S. Cl. CPC H01M 50/131; C23C 18/1651; C23C 18/32; C23C 18/38; C23C 18/42; H01M 50/119; H01M 50/121; H01M 50/1243; H01M 50/128; H01M 50/133; H01M 50/224; H01M 50/227; H01M 50/231; H01M 50/233; H01M 50/24; H01M 50/249; H01M 2220/20

(57) ABSTRACT

A battery cell, battery module, battery pack, or encased inverter has a housing with a fire resistant body. The fire resistant body includes: a thermoplastic substrate optionally free of flame retardants and having an inner surface and an opposite outer surface, and a nickel layer having a thickness of 10 to 60 microns plated on at least a portion of the inner surface, or both the inner surface and the outer surface of the thermoplastic substrate. The thermoplastic substrate has a plateable layer formed from a plateable composition containing at least one of acrylonitrile-butadiene-styrene, polycarbonate, polyetherimide, polysulfone, polyphenylene oxide, polyarylether, polytetrafluoroethylene, diallyl phthalate, polyacetal, poly ethersulfone, urea formaldehyde, phenolic, a blend of acrylonitrile-butadiene-styrene and a polyester, an acid functionalized polyethylene copolymer or an ionomer thereof, an acid functionalized polypropylene copolymer or an ionomer thereof, or an acid functionalized polyamide copolymer or an ionomer thereof.

### BACKGROUND

This disclosure relates to fire resistant articles, in particular fire resistant articles that can be used as housings or components of housings for batteries and inverters. The disclosure also relates to batteries or inverters including the fire resistant articles.

A battery pack generally has a housing and several battery modules accommodated in the housing, and a battery module can include a number of battery cells that are connected in series, parallel or a combination of both. Battery packs can be configured to deliver the desired voltage, capacity, or power density and are thus useful in a wide variety of applications. However, battery packs can be prone to thermal runaway due to short circuits, improper use such as overcharge, or exposure to extreme external temperatures or mechanical loads.

Batteries operate through oxidation and reduction reactions. Thermal runaway can occur when the reaction rate in a battery cell increases to the point that more heat is being generated than can be withdrawn, leading to a further increase in both reaction rate and heat generation. Eventually the amount of the heat generated is great enough to lead to the gassing or combustion of a battery cell.

During thermal runaway, a large amount of thermal energy can be rapidly released, heating the entire cell up to a temperature of 850° C. or more. Due to the increased temperature of the cell undergoing thermal runaway, the temperature of adjacent cells within the battery pack can also increase. If the temperature of these adjacent cells is allowed to increase without any control, they may also enter into a state of thermal runaway, leading to a cascading effect where the initiation of thermal runaway within a single cell propagates throughout the entire battery pack.

A number of approaches have been proposed to manage thermal runaway in batteries. Despite the extensive research, there is a continuing need for fire resistant articles that can be used in batteries or other electronic devices to reduce the risk of thermal runaway.

### SUMMARY

A device includes a housing having a fire resistant body, wherein the device is a battery cell, a battery module, a batter pack, or an encased inverter, and the fire resistant body includes a thermoplastic substrate optionally free of flame retardants, the thermoplastic substrate having a plateable layer formed from a plateable composition containing at least one of acrylonitrile-butadiene-styrene, polycarbonate, polyetherimide, polysulfone, polyphenylene oxide, polyarylether, polytetrafluoroethylene, diallyl phthalate, polyacetal, polyethersulfone, urea formaldehyde, phenolic, a blend of acrylonitrile-butadiene-styrene and a polyester, an acid functionalized polyethylene copolymer or an ionomer thereof, an acid functionalized polypropylene copolymer or an ionomer thereof, or an acid functionalized polyamide copolymer or an ionomer thereof, the thermoplastic substrate having an inner surface and an opposite outer surface; and a nickel layer plated on at least a portion of the inner surface, or at least a portion of both the inner surface and the outer surface of the thermoplastic substrate, the nickel layer having a thickness of 10 to 60 microns, preferably 15 to 50 microns, more preferably 20 to 45 microns.

In an aspect, the device is a battery cell including: a housing as described hereinabove; an electrolyte enclosed within the housing and facing the inner surface of the thermoplastic substrate; an anode and a cathode that are each in contact with the electrolyte; a separator separating the anode from the cathode; and a first terminal and a second terminal electrically coupled to the anode and cathode respectively and extending outwardly from the housing.

A battery module includes a plurality of electrically connected battery cells, wherein at least one of the battery cells is the above described battery cell.

In another aspect, the device is a battery module including the housing as described hereinabove and a plurality of electrically connected battery cells disposed in the housing and facing the inner surface of the thermoplastic substrate.

A battery pack includes a plurality of electrically connected battery modules, wherein at least one of the battery modules is the above described battery module.

In yet another aspect, the device is a battery pack including a housing as described hereinabove and a plurality of battery modules disposed in the housing hereinabove and facing the inner surface of the thermoplastic substrate.

In still another aspect, the device is an encased inverter having a housing as described hereinabove; and an inverter disposed within the housing and facing the inner surface of the thermoplastic substrate.

### BRIEF DESCRIPTION OF THE DRAWINGS

The following descriptions should not be considered limiting in any way. With reference to the accompanying drawings, like elements are numbered alike:

FIG. 1 is a cross-sectional view of a portion of an exemplary first resistant article;

FIG. 2 illustrates an exemplary fire resistant article during thermal runaway;

FIG. 3 is a perspective side view of an exemplary battery cell housing;

FIG. 4 is a partially cutaway perspective illustration of an exemplary battery cell with a fire resistant housing;

FIG. 5 is a schematic diagram of an exemplary battery module having a fire resistant housing;

FIG. 6 is a schematic diagram of an exploded structure of an exemplary battery pack having a fire resistant housing;

FIG. 7A and FIG. 7B show a nickel plated sample after the sample has been exposed to a continuous flame for 2.2 minutes, with FIG. 7A showing the front side that was exposed to the flame, and FIG. 7B showing the back side that was not exposed to the flame; and

FIG. 8 depicts electromagnetic shielding effectiveness as a function of frequency measured for a plated sample of Example 2.

### DETAILED DESCRIPTION

The inventors hereof have discovered articles that exhibit low thermal absorbance and high heat reflectance. These characteristics improve thermal insulation and increase flame or heat resistance of the articles thus allowing their use as thermal management barriers.

In addition, the articles can have a hard surface, which can withstand high energy impact such as particle impingement. During a thermal runaway event, battery cells eject particles which can damage materials/structures in proximity to the battery cells. The articles as disclosed herein have the ability to withstand particle impingement thus can minimize the impact caused by the ejected particles.

The articles also allow ferromagnetic dissipation of low frequency electromagnetic emissions (EMI) and can provide EMI shielding at low frequencies. This is advantageous as the metal-oxide-semiconductor field-effect transistors (MOSFETs) of inverters generate low frequency electromagnetic emissions in the range 30 kHz-1.5 MHz, and these emissions require ferromagnetic shielding on both inverter and battery cover to avoid undesired effects on the 12V lines.

The use of ceramic coatings has been considered to manage flammability and abrasion. However, these layers are difficult to apply and not electrically conductive and therefore do not reduce electromagnetic interference.

Aluminum foil is widely used for EMI management but it is only useful in the high frequency area (above 1 MHZ) since aluminum is paramagnetic and does not shield low frequency emissions efficiently.

An alternative is steel but the material is heavy and thermally and electrically conductive and can expose people to the high voltage of the battery systems if not handled properly.

The articles as described herein avoid the problems associated with articles with ceramic coatings, aluminum foils, or steel, and can be used as housings or a component thereof for inverters and batteries to shield heat/flame and electromagnetic interference, and to manage particle impingement.

The articles (also referred to as “fire resistant articles”) comprise a thermoplastic substrate having an inner surface and an opposite outer surface; and a nickel layer plated on at least a portion of the inner surface, or at least a portion of both the inner surface and the outer surface of the thermoplastic substrate.

The fire resistant articles can be a housing or a component thereof for an inverter or a battery such as a battery cell, a battery module, a battery pack, or a combination thereof. A component of the housing can include a body of the housing or a cover of the housing. The shape of the fire resistant articles is not particularly limited as long as they can form a housing to accommodate the batteries or inverters.

When the fire resistant articles are housings or a component thereof for a battery or an inverter, the inner surfacer means the surface that faces the battery or the inverter. Preferably a nickel layer is plated on at least a portion of the inner surface of the fire resistant articles, or at least a portion of the inner surface and an opposite outer surface of the fire resistant article. The presence of the nickel layer can contribute to the EMI shielding at low frequencies, heat insulation and flame resistance.

The thermoplastic substrate includes a plateable layer formed from a plateable composition comprising at least one of acrylonitrile-butadiene-styrene (ABS), polycarbonate, polyetherimide, polysulfone, polyphenylene oxide, polyarylether, polytetrafluoroethylene, diallyl phthalate, polyacetal, polyethersulfone, urea formaldehyde, phenolic, or a blend of ABS and a polyester such as polyethylene terephthalate (PET), polybutylene terephthalate (PBT), or a combination thereof, an acid functionalized polyethylene copolymer or an ionomer thereof, an acid functionalized polypropylene copolymer or an ionomer thereof, or an acid functionalized polyamide copolymer or an ionomer thereof. An acid functionalized polyethylene or polypropylene copolymer can include ethylene or propylene units and an acid functionalized olefine monomer such as 3-butenoic acid, 4-pentenoic acid, 10-undecenoic acid, or a combination thereof. The acid functionalized ethylene or propylene can also include a copolymer of ethylene and acrylic acid or a copolymer of propylene and acrylic acid. For example, the plateable composition can comprise an acid modified polypropylene containing 3-12 wt %, 5-12 wt %, 7 to 10 wt %, or 9 wt % of units derived from acrylic acid and 97-88 wt %, 95-88 wt %, 93-90 wt %, or 92 wt % of units derived from propylene. The acid functionalized ethylene or propylene copolymer can optionally include additional olefin units derived from propylene, ethylene, 1-butene, 3-methyl-1-butene, 1-pentene, 4-methyl-1-pentene, 1-hexene, vinyl cyclohexane, or a combination thereof. In addition, the acid functionalized polyethylene or polypropylene copolymer can be treated with a salt such as a metal salt or an ammonium salt to form an ionomer having ionic bonds derived from the acid functional group.

These polymers or polymer blends can be present in an amount of 50 weight percent to 99 weight percent, or 60 to 99 weight percent, 70 to 99 weight percent, or 80 to 99 weight percent based on the total weight of the plateable composition.

Preferably the plateable layer is an ABS layer formed from an ABS composition having a butadiene content of 5 to 30 weight percent based on a total weight of the ABS composition. The butadiene content can be tuned by adjusting the amount of the ABS in the ABS composition as well as the percent of butadiene unit in the ABS polymer. The ABS composition can include only ABS as the polymer component. Alternatively, the ABS composition can comprise a blend of ABS and a polycarbonate, or a blend of ABS and a polyester such as PET, PBT, or a combination thereof. The ABS composition can comprise 30 to 75 weight percent of a polycarbonate or polyester, based on the total weight of the ABS composition. A weight ratio of the polycarbonate or polyester relative to the ABS can be 1:5 to 5:1 or 2:5 to 4:1.

The plateable composition such as the ABS composition can further contain various additives, with the proviso that the additives are selected to not adversely affect the desired properties of the substrate, in particular, rigidity, impact resistance, insulating properties, and abrasion and strain resistance. Such additives can be mixed at a suitable time during the mixing of the components of the plateable composition. Examples of the additives include impact modifiers, fillers, reinforcing agents, antioxidants, heat stabilizers, light stabilizers, ultraviolet (UV) light stabilizers, plasticizers, lubricants, mold release agents, antistatic agents, colorants (such as carbon black and organic dyes), surface effect additives, radiation stabilizers (e.g., infrared absorbing), and anti-drip agents. A combination of additives can be used. The total amount of additives (other than any impact modifier, filler, or reinforcing agents) can be 0.001 weight percent to 5 weight percent, based on the total weight of the plateable composition. In an embodiment, the plateable composition comprises at least one of a reinforcement filler, a flow promoter, an anti-oxidant, or a mold release agent.

Advantageously, the thermoplastic substrate and the plateable composition can be free of flame retardants. Due to the high reflectance of the nickel plated articles, the thermoplastic substrate can survive a two minute exposure to a flame even when the thermoplastic substrate does not contain flame retardants. Thus the nickel plating of thermoplastics offers an alternative to use of intumescent formulations and the capability of flame resistance in a non-flame retarded material (provided the surface is nickel plated) as well as in a flame retarded one. This is advantageous because flame retardants may leach out into plating baths affecting plating under certain circumstances, and intumescence additives can limit thermal loads on the nickel plated thermoplastics articles. Given the high cost of flame retardants and intumescence additives, fire resistant articles that are free of flame retardants and intumescence additives can have an economic advantage. Moreover, the thermoplastic in such articles can be recycled without concerns for the flame retardant additives.

The plateable composition can be molded into useful shaped articles by a variety of methods, such as injection molding, extrusion, rotational molding, blow molding and thermoforming, thereby forming the thermoplastic substrate.

The thermoplastic substrate can include only one layer, for example, a plateable layer formed from the plateable composition. The thermoplastic substrate can also include two or more layers, for example a plateable ABS layer and a polycarbonate layer dispersed in the ABS layer.

The thermoplastic substrate can have a thickness of 1.5 to 6 millimeters (mm), preferably 2.5 to 5 mm, more preferably 2.5 to 3.5 mm. The nickel layer can have a thickness of 10 to 60 microns, preferably 15 to 50 microns, more preferably 20 to 45 microns. The thickness of the nickel layer relative to the thickness of the thermoplastic substrate is 1:100 to 1:500, preferably 1:100 to 1:400, and more preferably 1:100 to 1:250 or 1:100 to 1:200.

The nickel layer can include only one layer or a combination of two or more, for example two to five, two to four, or two to three different sublayers. A combination of different sublayers may provide corrosion resistance, ensure good adhesion and thermal cycle performance. Preferably the nickel layer has at least two layers, a semi-bright nickel layer (e.g. sulfur-free semi-bright nickel layer) and a bright nickel layer. The bright nickel layer can be disposed on the semi-bright nickel layer, and the semi-bright nickel layer can be the layer adjacent the thermoplastic substrate. The semi-bright nickel layer can have a thickness of 4 to 40 microns, 10 to 40 microns, or 15 to 30 microns. The bright nickel layer can have a thickness of 5 to 40 microns, 5 to 20 microns or 5 to 15 microns.

The fire resistant articles can further comprise a copper layer disposed between the thermoplastic substrate and the nickel layer. When present, the copper layer can be plated directly on the thermoplastic substrate, and the nickel layer, for example, semi-bright nickel layer, is then plated on the copper layer. A thickness of the copper layer can be 10 to 40 microns, preferably 10 to 35 microns, more preferably 10 to 30 microns. The copper layer can facilitate heat insulation and flame resistance.

The fire resistant articles can further comprise palladium between the thermoplastic substrate and the copper layer or between the thermoplastic substrate and the nickel layer if the copper layer is not present. The presence of palladium allows a copper layer or a nickel layer to be plated on the thermoplastic substrate.

Optionally the fire resistant articles further comprise a chrome layer disposed on the nickel layer. The nickel layer has a first surface facing the thermoplastic substrate and an opposite second surface. Preferably the chrome layer is disposed on the second surface of the nickel layer. The chrome layer can have a thickness of 0.1 to 10 microns, preferably 0.1 to 5 microns, more preferably 0.1 to 1 micron. The presence of the chrome layer increases the hardness of the fire resistant articles and contributes to the ability of the articles to withstand particle impingement. The presence of the chrome layer can also act reflective of visible and infrared light reducing thermal loads on the thermoplastic substrate.

The fire resistant articles can have an electromagnetic shielding efficiency of greater than 30 decibel (dB), for example 40 to 60 dB or 45 to 60 dB at 30 megahertz (MHz) to 15 gigahertz (GHz) as determined by ASTM D4935.

To produce fire resistant articles, a thermoplastic substrate can be pretreated to remove contaminations such as grease, dirt, and debris from the surface to be plated. Surfactants, alkaline cleaners, or other suitable cleaners known in the art may be used. As a specific example, a water bath with soaps is used to facilitate dust removal from the thermoplastic substrate.

The cleaned thermoplastic substrate can then undergo an etch process to roughen or functionalize the surface to be plated so that efficient bonding between the substrate and a copper layer or a nickel layer may be provided. For example an etch solution is applied to the thermoplastic substrate, and the etchant in the etch solution can chemically react with the surface of the thermoplastic substrate, introducing microscopic pores or voids, which can act as sites for catalyst absorption during subsequent steps. Etchants can include chromic acid, chromium trioxide, or sulfuric acid solutions. Wetting agents can also be used to aid in the wetting of the surface during the etch operation. In an embodiment, chromic acid can oxidize butadiene on the surface of the thermoplastic substrate to be plated, which creates structures for mechanical bonding sites.

After etching, the excess etchant can be removed, for example, by rinsing. Applying a neutralizer can further ensure that any excess etchant is completely eliminated. During neutralization, hexavalent chrome, if used, can be converted to trivalent chrome. Hexavalent chrome can interfere with the subsequent activation process if allowed to come into contact with the activated surface. Hexavalent chrome contamination may also result in areas of the parts not being plated uniformly if not removed. The neutralizer can include complexing agents such as polyamines, and reducing agents such as hydroxylamine and bisulfite, or any other suitable neutralizer known in the art for removal of etchants.

The etched surface can then be treated with an activator to form a catalytically active surface for subsequent electroless metal plating. The activator can be a low-concentration precious metal liquid activator that serves as a catalyst during plating. The precious metals found in activators can include at least one of palladium, platinum, or gold. Palladium is preferred.

Colloidal systems can be utilized to activate the etched surface. For example, solutions of colloidal palladium are generally utilized, and the colloidal palladium can be formed from the reaction between palladium chloride and stannous chloride in the presence of excess of hydrochloric acid (Annual Book of ASTM Standard, Vol. 02.05 “Metallic and Inorganic Coatings; Metal Powders, Sintered P/M Structural Parts”, Designation: B727-83, Standard Practice for Preparation of Plastic Materials for Electroplating, 1995, pages 446-450). During activation, palladium particles can attach to the etched surface, for example, absorbed in the pores or voids of the etched surface of the thermoplastic substrate. Subsequently, an acid bath such as HBF₄ bath can be used to chemically remove the tin from the outside of the activator colloid, leaving the palladium exposed for subsequent electroless plating.

The activated thermoplastic substrate can then be placed in an electroless bath to deposit a copper or nickel layer to make the surface of the thermoplastic substrate conductive. Electroless plating on the thermoplastic substrate can include all-over plating or selective plating. With the former, the copper or nickel is deposited over the entire surface of the thermoplastic substrate, for example both the inner surface and the outer surface of the thermoplastic substrate. Selective plating includes depositing the metal onto specific surfaces of the thermoplastic substrate, for example only on the inner surface or only on the outer surface of the substrate.

If selective plating is desired, the portion of the thermoplastic substrate that does not need to be plated can be masked, then the plating catalyst is sprayed only onto the areas where plating is needed. The catalyzed substrate is then loaded into a plating fixture and immersed into an electroless plating chemical tank to deposit copper plating or zinc plating onto specified areas. Other known selective plating methods can also be used.

After electroless plating, copper or zinc can optionally deposit on the thin zinc or copper layer plated with electroless plating from a copper strike bath or a zinc strike bath to improve conductivity, allowing the thermoplastic substrate to be further processed without causing plating defects due to the increasingly higher voltages that are required by the subsequent plating. This step is the initial electrolytic (with current) plating which is run at very low amperage in order to build up plating thickness. The electroplated copper or zinc layer may be from 0.1 to 3 micron thick depending on the material used.

Subsequently, a copper layer can be deposited to add leveling ductility. During the step, copper is deposited at higher current in a copper bath such as a copper acid bath containing copper ions and an acid. This layer of copper can level out the microscopically rough surface created in the etch step and provides the plated part its leveling and brightness. The thickness of the copper layer can vary from 10 to 40 microns depending on the ductility and amount of leveling needed for the application.

A bath consisting of hydrogen peroxide and sulfuric acid can be used to remove an organic brightener film left on the thermoplastic substrate after copper plating. This can facilitate adhesion between the copper layer and the nickel layer which is plated in the next bath. Without this step there could be a lack of adhesion between metal layers resulting in delamination.

The thermoplastic substrate can then be submerged in a nickel plating bath. An electric current is applied to the thermoplastic substrate, which causes the nickel particles to attach and bind to the surface of the copper layer on the thermoplastic substrate forming the nickel layer.

The nickel layer can include only one layer or a combination of two or more, for example two to five, or two to four, or two to three different sublayers. In an embodiment, the nickel layer includes at least one of a semi-bright nickel layer, a high sulfur nickel layer, a bright nickel layer, or a porous nickel layer.

A semi-bright nickel layer can be free of sulfur and is very noble (non-reactive) in nature and this contributes greatly to the ultimate corrosion protection of the thermoplastic substrate. A semi-bright nickel layer can also promote adhesion and improve EMI shielding performance. The grain structure of semi-bright nickel deposits is usually columnar, and the nickel can be deposited from a semi-bright nickel solution. Additives for the semi-bright nickel solution are known and have been described for example in nickel plating handbook 2014 from nickel institute. This layer can have a thickness of 4 to 40 microns.

The nickel layer can include a high sulfur nickel layer. This layer can be a sacrificial high sulfur nickel layer to provide small sites for corrosion to prevent corrosion in large sites. The high sulfur nickel layer can have a thickness of 1 to 2 microns. It can be deposited between sulfur-free semi-bright and bright nickel layers. If used, this layer can produce a dramatic improvement in corrosion protection because it is a very active deposit, which can sacrificially corrode during use. The electrolyte for depositing the high sulfur nickel layer may be a Watts-type nickel plating bath or a semi-bright nickel bath but further containing a thiazole and/or thiazoline additive compound or other known suitable sulfur-containing compound in appropriate amounts to achieve the requisite sulfur content in the high sulfur nickel layer.

The nickel layer can include a bright nickel layer. The layer adds luster, sheen and corrosion protection. A bright nickel deposit that restores the brightness of the thermoplastic substrate after semi-bright nickel plating. Primary brightener can include saccharin, which supplies sulfur to be co-deposited with the nickel. The bright nickel thickness can range from 5 to 40 microns depending on what environment the application is submitted to. The bright nickel bath is known and has been described for example in nickel plating handbook 2014 from nickel institute. A satin nickel is another option in place of bright nickel. A satin nickel deposit that achieves the satin color and reflectivity by controlling the amount of organic additives to the bath.

The nickel layer can also include a porous nickel (Dur-Ni) layer. This layer can have a thickness of 1 to 3 microns. The plating bath for the porous nickel layer can inert particles which are encapsulated during plating within the nickel layer. The particles can provide high micro-porosity in the subsequent chromium layer. In an embodiment, the porosity is greater than or equal to 64,000 pores/square inch of surface area, for example, 64,000 pores/square inch to 150,000 pores/square inch.

Optionally a chrome layer is electroplated on the nickel layer. Flash chrome plating can be used, and the process conditions are known to a person skilled in the art.

Before chromate plating, the porous nickel surface can be activated in a nickel activator bath (e.g. an acid solution) with a slight amount of electric current so that it will be receptive to chromium plating. Low current density area of the thermoplastic substrate may not be receptive to chromium coverage if not properly activated.

Chrome plating can provide a hardened, corrosion resistant, and reflective chrome surface. Chromium will only adhere where there is nickel, and if Dur-Ni nickel layer is used, chrome can plate around the microscopic inert particles contained in the Dur-Ni nickel layer, leaving a microporous surface.

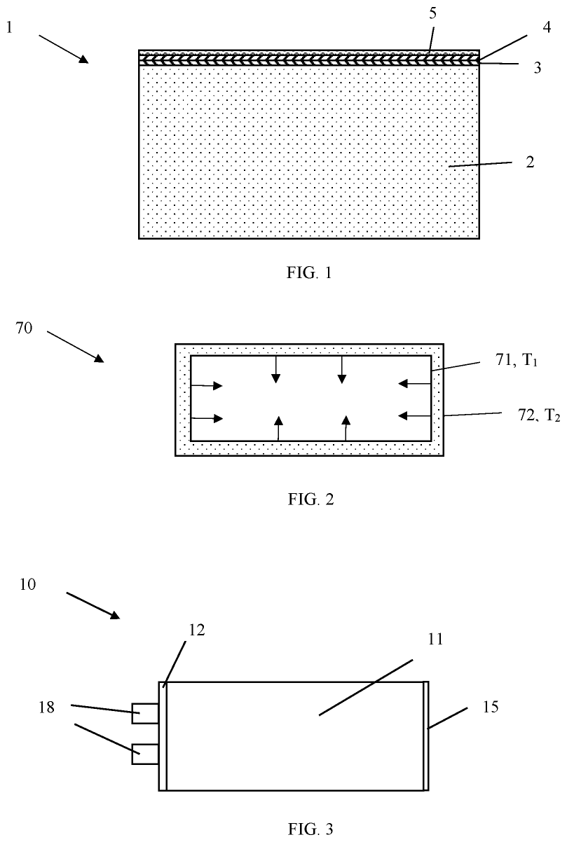

FIG. 1 is a cross-sectional view of a portion of an exemplary fire resistant article. As shown in FIG. 1, a fire resistant article 1 comprises a thermoplastic substrate 2, a copper layer 3 plated on an inner surface of the thermoplastic substrate, and a nickel layer 4 plated on the copper layer. The fire resistant article 1 also includes a chrome layer 5 disposed on the nickel layer. The copper, nickel, and chrome layers can also be plated on the outer surface of the thermoplastic substrate (not shown).

The fire resistant articles as described herein have excellent flame resistance and can withstand at least 2 minutes when exposed to a 700° C. or 800° C. flame. As illustrated in FIG. 2, the fire resistant article 70 can deflect heat, and as a result, when the inner surface 71 is subjected to a 700° C. or 800° C. flame, its surface temperature T1 can be about 400° C. and the opposing surface 72 can have a temperature T2 less than 120° C. The fire resistant articles can be used as housings or a component thereof for inverters and batteries including battery cells, battery modules, battery packs, or a combination thereof.

Referring to FIG. 3, in other embodiments, a battery cell housing can include a body 11, a top cover 12, and a bottom cover 15, wherein the body 11, the top cover 12, the bottom cover 15, or a combination thereof, can be a fire resistant article as described herein. Preferably at least the body 11 is a fire resistant article. The terminals 18 for the battery cell 10 can extend through the top cover 12 from inside the body 11. The body 11, the top cover 12, and the bottom cover 15 can be assembled together using mechanical and/or chemical methods, such as fasteners, adhesives, or welding (e.g., laser welding). Other known techniques can also be used. The bottom cover 15 and the body 11 can be a one piece structure, and in this instance, the housing of the battery cell 10 only includes a top cover and a body.

Battery cells having a housing including a fire resistant article such as a fire resistant body are also disclosed. The battery cells include a housing, an electrolyte facing the inner surface of the thermoplastic substrate, a positive electrode (cathode), a negative electrode (anode), and a separator disposed between the anode and cathode. The materials and configuration (if applicable) for the electrolyte, electrodes, and separator are known and not particularly limited. The battery cells can be cylindrical cells, prismatic cells, or pouch cells. Referring to FIG. 4, an example of battery cell 20 includes a housing 22, a cathode 28, an anode 21, and a separator 27 disposed between the cathode 28 and anode 21. The battery cell 20 also includes an insulator 26, a cathode tab or terminal 24 and an anode tab or terminal 23. Electrolyte 25 can be disposed within the housing 22.

The battery cells can be used in lithium ion batteries such as lithium iron phosphate batteries, ternary lithium batteries, solid-state lithium ion batteries, and the like. As used herein, lithium ion batteries include rechargeable lithium ion batteries.

More than one battery cells can be used. Accordingly, also disclosed is a battery module comprising a plurality of electrically connected battery cells, e.g., connected in series, or connected in parallel, or connected in a combination thereof.

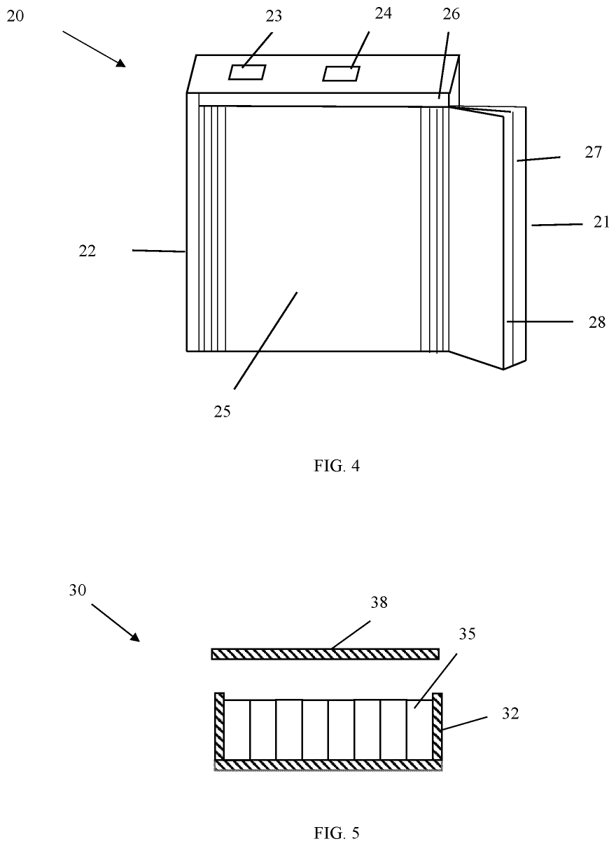

Referring to FIG. 5, a battery module 30 can include a plurality of battery cells 35 facing the inner surface of the thermoplastic substrate and a housing that enclose the battery cells. The housing can include a body 32 and a cover 38. The body 32, the cover 38, the housing for the battery cells 35, or a combination thereof can independently include a fire resistant article as described herein. Preferably at least the body 32 is a fire resistant article.

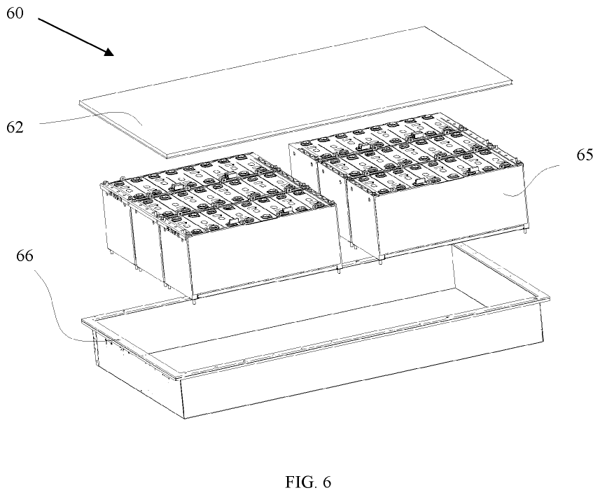

The battery modules can be assembled together forming a battery pack. Referring to FIG. 6, a battery pack 60 can have a housing including a body 66 and a cover 62, and battery modules 65 enclosed within the housing and facing the inner surface of the thermoplastic substrate. The body 66, the cover 60, the housings for the battery pack 65, the housings for the battery cells, or a combination thereof can independently include a fire resistant article as described herein. The battery modules can be electrically connected in the battery packs.

The battery cells, the battery modules, and the battery packs can be used in electric vehicles, hybrid vehicles, plug-in hybrid electric vehicles, consumer electronics, or other products where batteries are used.

As described herein, the fire resistant articles can also be used as a housing or a component thereof for inverters. An encased inverter can thus have a housing comprising a fire resistant article (fire resistant body) as described herein; and an inverter disposed within the housing and facing the inner surface of the thermoplastic substrate.

The above described and other features are exemplified by the following examples.

### EXAMPLES

### Example 1

The material used in the example is described in Table 1. The material is a commercial grade and did not have any additives to increase flame retardance or achieve high temperature performance.

TABLE 1

| Thermoplastic composition | Source, Vendor |
|---|---|
| Thermoplastic alloy of polycarbonate and | SABIC |
| Acrylonitrile-butadiene-styrene (CYCOLOY ™) | |

The thermoplastic composition was molded under conditions shown in Table 2 to form a thermoplastic substrate.

TABLE 2

| Description | Unit | Conditions |
|---|---|---|
| Pre-drying temperature | ° C. | 100-150 |
| Pre-drying time | hour | 3-4 |
| Zone 1 temperature | ° C. | 255-280 |
| Zone 2 temperature | ° C. | 255-290 |
| Zone 3 temperature | ° C. | 255-290 |
| Nozzle temperature | ° C. | 260-290 |
| Molding temperature (melt) | ° C. | 260-290 |
| Molding temperature (mold) | ° C. | 40-70 |

Several 6×6 inch square plates were molded using the thermoplastic composition. These plates were subject to an electroless plating process involving chromic acid etching, followed by Pd deposition, electroless copper and nickel deposition. The process was optimized to reach a 20 micron plating thickness using smaller 3×4 inch square coupons.

The flammability test was performed using a propane torch with a maximum temperature of 1500° C. and a vertical sample holder placed at a fixed distance from the torch. The gas flow was throttled until a reading in excess of 1000° C. was measured using a K type thermocouple at a 3 inch distance from the tip of the torch. A 1 mm thick steel plate was slid into the sample holder and the temperature on its surface was measured using an infrared camera. After confirming the ability to exceed 850° C. within 1 minute, the steel plate was replaced by the plated sample and held for 2.2 minutes under continuous flame exposure. The torch was turned off after 2.2 minutes.

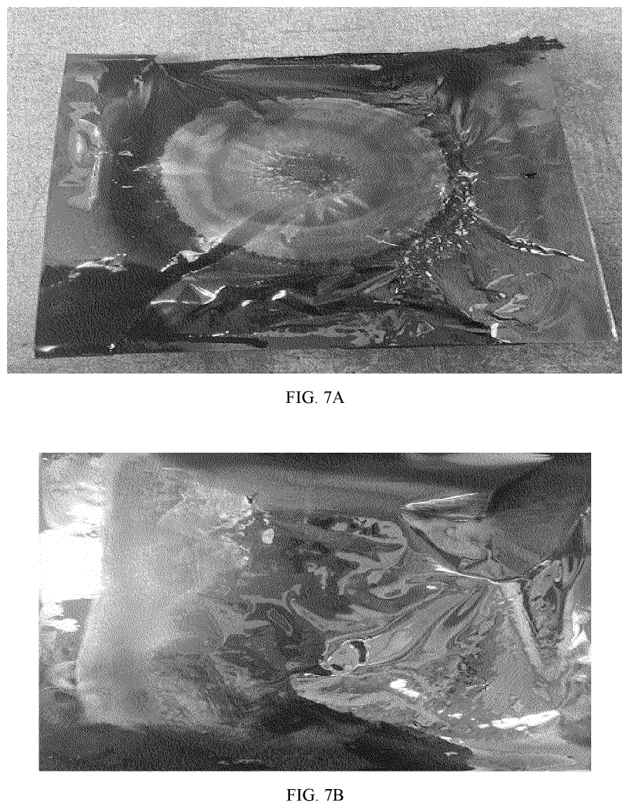

As shown in FIG. 7A, a circular pattern formed on the nickel layer and it bulged out due to thermal expansion. The plated layer also exhibited lower peak surface temperatures than steel (around 400° C.) due to its ability to reflect radiative heat. The back side showed considerably lower temperatures (<120° C.) throughout the test. The edges of the plated sample cracked exposing the underlying material to flame and caught fire. This fire extinguished completely after the torch was turned off. The sample retained its original geometry and rigidity after removal from the sample holder as shown in FIG. 7B. Inspection showed that both front and back layers were intact with no surface cracks developing in the nickel layer.

### Example 2

Plates were molded using the thermoplastic composition of Table 1 under the conditions shown in Table 2. These plates were subject to an electroless plating process involving chromic acid etching, followed by Pd deposition, electroless copper and nickel deposition, and chrome deposition. The copper, nickel, and chrome layers have a thickness of 15 microns, 30 microns, and 0.25 micron respectively.

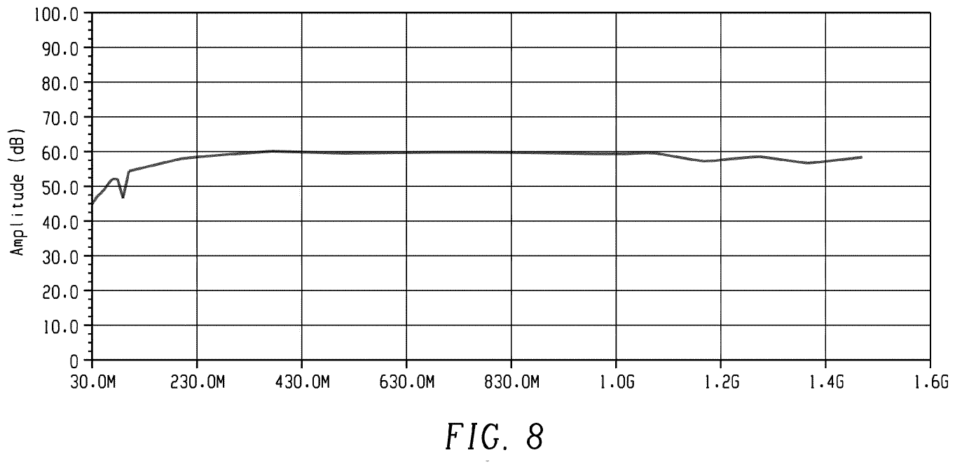

The electromagnetic shielding effectiveness was measured according to the ASTM D4935 at 30 kilohertz (kHz) to 15 gigahertz (GHz). The shielding effectiveness results are depicted in FIG. 8. The results indicate that the plated sample has excellent electromagnetic shielding efficiency of 40 to 60 decibel (dB) or 45 to 60 dB at 30 megahertz (MHz) to 15 gigahertz (GHz) as determined by ASTM D4935.

A flammability test was performed on the plated sample of Example 2 according to the procedure of Example 1 with a temperature of 1200° C. and a test duration of 5 minutes. The results indicate that the plating layer can survive the fire at 1200° C. and protect the material (thermoplastic substrate) underneath.

All cited patents, patent applications, and other references are incorporated herein by reference in their entirety. However, if a term in the present application contradicts or conflicts with a term in the incorporated reference, the term from the present application takes precedence over the conflicting term from the incorporated reference.

While typical embodiments have been set forth for the purpose of illustration, the foregoing descriptions should not be deemed a limitation on the scope herein. Accordingly, various modifications, adaptations, and alternatives can occur to one skilled in the art without departing from the spirit and scope herein.

1. A device comprising a housing having a fire resistant body,
wherein the device is a battery cell, battery module, battery pack, or encased inverter, and
the fire resistant body comprises:
a thermoplastic substrate having an inner surface and an outer surface,
the thermoplastic substrate comprising
a plateable layer formed from a plateable composition comprising at least one of acrylonitrile-butadiene-styrene, polycarbonate, poly etherimide, polysulfone, polyphenylene oxide, polyarylether, polytetrafluoroethylene, diallyl phthalate, polyacetal, poly ethersulfone, urea formaldehyde, phenolic, a blend of acrylonitrile-butadiene-styrene and a polyester, an acid functionalized polyethylene copolymer or an ionomer thereof, an acid functionalized polypropylene copolymer or an ionomer thereof, or an acid functionalized polyamide copolymer or an ionomer thereof; and
a nickel layer plated on at least a portion of the inner surface of the thermoplastic substrate, or at least a portion of both the inner surface and the outer surface of the thermoplastic substrate,
the nickel layer having a thickness of 10 to 60 microns.

2. The device of claim 1, wherein
the plateable layer is an acrylonitrile-butadiene-styrene layer formed from an acrylonitrile-butadiene-styrene composition having a butadiene content of 5 to 30 weight percent based on a total weight of the acrylonitrile-butadiene-styrene composition.

3. The device of claim 2, wherein
the acrylonitrile-butadiene-styrene composition further comprises 30 to 75 weight percent of a polycarbonate or a polyester, based on the total weight of the acrylonitrile-butadiene-styrene composition.

4. The device of claim 2, wherein
the thermoplastic substrate further comprises a polycarbonate layer disposed on the acrylonitrile-butadiene-styrene layer.

5. The device of claim 1, wherein
the thermoplastic substrate has a thickness of 1.5 to 6 mm.

6. The device of claim 1, wherein
the fire resistant body further comprises a copper layer disposed between the thermoplastic substrate and the nickel layer.

7. The device of claim 6, wherein
the copper layer has a thickness of 10 to 40 microns.

8. The device of claim 1, wherein
the nickel layer has a first surface facing the thermoplastic substrate and an opposite second surface, and the fire resistant body of the housing further comprises a chrome layer disposed on at least a portion of the second surface of the nickel layer.

9. The device of claim 8, wherein
the chrome layer has a thickness of 0.1 to 10 microns.

10. The device of claim 1, wherein
the device is a battery cell comprising:
the housing;
an electrolyte enclosed within the housing and facing the inner surface of the thermoplastic substrate;
an anode and a cathode that are each in contact with the electrolyte;
a separator separating the anode from the cathode; and
a first terminal and a second terminal electrically coupled to the anode and cathode respectively and extending outwardly from the housing.

11. A battery module comprising
a plurality of electrically connected battery cells,
wherein at least one of the battery cells is the battery cell of claim 10.

12. The device of claim 1, wherein
the device is a battery module comprising:
the housing; and
a plurality of electrically connected battery cells disposed in the housing and facing the inner surface of the thermoplastic substrate.

13. A battery pack comprising
a plurality of battery modules,
wherein at least one of the battery modules is a battery module of claim 12.

14. The device of claim 1, wherein
the device is a battery pack comprising
a plurality of battery modules disposed in the housing and facing the inner surface of the thermoplastic substrate.

15. The device of claim 1, wherein
the device is an encased inverter comprising:
the housing; and
an inverter disposed within the housing and facing the inner surface of the thermoplastic substrate.

16. The device of claim 1, wherein the thermoplastic substrate is free of a flame retardant.

17. The device of claim 1, wherein the nickel layer has a thickness of one: 15 to 25 microns; or 20 to 45 microns.

18. The device of claim 5, wherein the thermoplastic substrate has a thickness of one of: 2.5 to 5 mm; or 2.5 to 3.5 mm.

19. The device of claim 7, wherein the copper layer has a thickness of one of: 10 to 35 microns; or 10 to 30 microns.

20. A vehicle, comprising:
a battery pack, the battery pack including a battery pack housing, wherein the battery pack housing includes battery pack body and a battery pack cover;
a plurality of battery modules disposed within the battery pack housing, each of the battery modules including a battery module housing, wherein the battery module housing includes a battery module body and battery module cover;
a plurality of battery cells within the battery module housing, each of the battery cells including a battery cell housing, wherein the battery cell hosing includes a battery cell body, a battery cell top cover, and a battery cell bottom cover, a cathode, an anode, and a separator disposed between the cathode and anode, an insulator, a cathode terminal, and an anode terminal, an electrolyte disposed within the battery cell housing;
wherein one or more of:
the battery pack housing, or portion thereof, is formed of a fire resistant article;
the battery module housing, or portion thereof, is formed of the fire resistant article; or
the battery cell housing, or portion thereof, is formed of the fire resistant article,
wherein the fire resistant article comprises:
a thermoplastic substrate;
copper layer plated on an inner surface of the thermoplastic substrate;
nickel layer plated on the copper layer; and
chrome layer disposed on the nickel layer,
wherein the thermoplastic substrate comprises:
a plateable layer formed from a plateable composition comprising at least one of acrylonitrile-butadiene-styrene, polycarbonate, poly etherimide, polysulfone, polyphenylene oxide, polyarylether, polytetrafluoroethylene, diallyl phthalate, polyacetal, poly ethersulfone, urea formaldehyde, phenolic, a blend of acrylonitrile-butadiene-styrene and a polyester, an acid functionalized polyethylene copolymer or an ionomer thereof, an acid functionalized polypropylene copolymer or an ionomer thereof, or an acid functionalized polyamide copolymer or an ionomer thereof,
wherein the nickel layer having a thickness of 10 to 60 microns, and
wherein the vehicle is one of an electric vehicle; a hybrid vehicle; or a plug-in hybrid electric vehicle.
